(19) United States
(12) Patent Application Publication
(10) Pub. No.: US 2026/0047109 A1
(43) Pub. Date: Feb. 12, 2026

(54) SEMICONDUCTOR DEVICE INCLUDING DEEP TRENCH CAPACITOR AND MANUFACTURING METHOD THEREOF

(71) Applicant: SK keyfoundry Inc., Cheongju-si (KR)

(72) Inventor: Jonghyuk OH, Cheongju-si (KR)

(73) Assignee: SK keyfoundry Inc., Cheongju-si (KR)

(21) Appl. No.: 18/958,668

(22) Filed: Nov. 25, 2024

(30) Foreign Application Priority Data
Aug. 9, 2024 (KR) 10-2024-0106629

(51) Int. Cl. H10D 1/00; H10D 1/68

(52) U.S. Cl. CPC H10D 1/042; H10D 1/716

(57) ABSTRACT

A method of manufacturing a semiconductor device with a deep trench capacitor includes forming first and second deep trenches in a substrate; forming a highly doped first polysilicon layer in the first and second deep trenches; forming a dielectric layer on the highly doped first polysilicon layer; forming a highly doped second polysilicon layer on the dielectric layer; performing a first etch process on the highly doped second polysilicon layer to form first and second upper electrodes in the first and second deep trenches; forming an insulating layer; performing a second etch process on the insulating layer to form first and second spacers; forming a silicide layer; forming an inter-metal insulating layer on the silicide layer; forming contact plugs on the silicide layer; and forming a metal layer connected to each of the contact plugs. The highly doped first polysilicon layer is a single continuous layer formed in the first deep trench and the second deep trench.

### CROSS REFERENCE TO RELATED APPLICATION

The present application claims the benefit under 35 U.S. C. § 119(a) of Korea Patent Application No. 10-2024-0106629 filed on Aug. 9, 2024 in the Korea Intellectual Property Office, the entire disclosure of which is incorporated herein by this reference for all purposes.

### BACKGROUND

### 1. Field

The following description relates to a semiconductor device comprising a deep trench capacitor and a manufacturing method thereof.

### 2. Description of the Related Art

A semiconductor device comprising a deep trench capacitor in a semiconductor substrate has been used in one method of increasing the total capacitance of a capacitor structure. A plurality of the deep trench capacitors may be formed vertically in the semiconductor substrate to reduce the chip area of the capacitor structure. In order to reduce manufacturing costs, there has been a need to simplify the manufacturing method of semiconductor devices comprising deep trench capacitors. There is also a need to miniaturize the semiconductor devices comprising deep trench capacitors in order to reduce the chip size of integrated circuits.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Therefore, various examples of the present disclosure may provide a manufacturing method of the semiconductor device comprising deep trench capacitors, and may also provide a compact size of the semiconductor device comprising deep trench capacitors.

The technical problems that the present disclosure seeks to overcome are not limited to the technical problems described above, and other technical problems that are not mentioned will be clearly understood by ordinary-skilled persons in the art to which the present disclosure pertains from the following description.

In one general aspect, a method of manufacturing a semiconductor device including a deep trench capacitor includes: forming a first deep trench and a second deep trench in a substrate; forming a highly doped first polysilicon layer in the first deep trench and the second deep trench; forming a highly doped first polysilicon layer in the first deep trench and the second deep trench; forming a dielectric layer on the highly doped first polysilicon layer; forming a highly doped second polysilicon layer on the dielectric layer; performing a first etch process on the highly doped second polysilicon layer to form a first upper electrode and a second upper electrode in the first deep trench and the second deep trench, respectively, wherein a first dielectric layer is formed between the first upper electrode and the highly doped first polysilicon layer and a second dielectric layer is formed between the second upper electrode and the highly doped first polysilicon layer by performing the first etch process; forming an insulating layer on the first upper electrode and the second upper electrode; performing a second etch process on the insulating layer to form a first spacer on sidewalls of the first dielectric layer and the first upper electrode and a second spacer on sidewalls of the second dielectric layer and the second upper electrode; forming a silicide layer on the highly doped first polysilicon layer, the first upper electrode and the second upper electrode; forming an inter-metal insulating layer on the silicide layer; forming contact plugs on the silicide layer; and forming a metal layer connected to each of the contact plugs, wherein the highly doped first polysilicon layer is a single continuous layer in the first deep trench and the second deep trench.

The silicide layer may include a first silicide layer disposed on the highly doped first polysilicon layer adjacent to the first spacer; a second silicide layer disposed on the first upper electrode and having a horizontal length greater than a horizontal length of the first silicide layer; a third silicide layer disposed on the highly doped first polysilicon layer located between the first spacer and the second spacer; a fourth silicide layer disposed on the second upper electrode and having a horizontal length greater than a horizontal length of the first silicide layer; and a fifth silicide layer disposed on the highly doped first polysilicon layer adjacent to the second spacer.

A doping concentration of the highly doped first polysilicon layer may be the same as a doping concentration of the first upper electrode and the second upper electrode, and the doping concentration of the highly doped first polysilicon layer may be in a range of 1E18 to 1E21 atoms/cm³.

The number of the contact plugs formed on the second or fourth silicide layer may be greater than a number of the contact plugs formed on the first, third, or fifth silicide layer.

The method may further include performing a high temperature annealing process on the highly doped first polysilicon layer or the highly doped second polysilicon layer in a gas mixture of oxygen gas and inert gas. A partial pressure of the oxygen gas may be less than 1% of a total pressure of the gas mixture.

The substrate may include a highly doped substrate and an epitaxial layer, and the first and second deep trenches may be formed in the epitaxial layer.

In another general aspect, a semiconductor device including a deep trench capacitor includes: a first deep trench and a second deep trench formed in a substrate; a single continuous highly doped first polysilicon layer disposed in the first deep trench and the second deep trench; a first dielectric layer and a second dielectric layer formed on the single continuous highly doped first polysilicon layer and disposed in the first deep trench and the second deep trench, respectively; a first upper electrode and a second upper electrode formed on the first dielectric layer and the second dielectric layer, respectively, and formed in the first deep trench and the second deep trench, respectively; a first spacer formed on sidewalls of the first dielectric layer and the first upper electrode; a second spacer formed on sidewalls of the second dielectric layer and the second upper electrode; a first silicide layer formed on the single continuous highly doped first polysilicon layer adjacent to the first spacer; a second silicide layer formed on the first upper electrode, the second silicide layer having a horizontal length greater than a horizontal length of the first silicide layer; a third silicide layer formed on the single continuous highly doped first polysilicon layer disposed between the first spacer and the second spacer; a fourth silicide layer formed on the second upper electrode, the fourth silicide layer having a horizontal length greater than a horizontal length of the first silicide layer; a fifth silicide layer formed on the single continuous highly doped first polysilicon layer adjacent to the second spacer; an inter-metal insulating layer formed on the first to the fifth silicide layers; a first contact plug, a second contact plug, a third contact plug, a fourth contact plug and a fifth contact plug connected to the first, second, third, fourth and fifth silicide layers, respectively; and a first metal layer, a second metal layer, a third metal layer, a fourth metal layer and a fifth metal layer connected to the first, second, third, fourth and fifth contact plugs, respectively.

A doping concentration of the single continuous highly doped first polysilicon may be in a range of 1E18 to 1E21 atoms/cm³.

The substrate may include a highly doped substrate and an epitaxial layer, and the first and second deep trenches may be formed in the epitaxial layer.

The single continuous highly doped first polysilicon layer may include a same material as the first and second upper electrodes.

Each of the second contact plug and the fourth contact plug may have at least two contact holes, and each of the first, third and fifth contact plugs may have fewer contact holes than the second or fourth contact plug.

Effects which may be obtained by the present disclosure are not limited to the aforementioned effects, and other technical effects not described above may be evidently understood by a person having ordinary skill in the art to which the present disclosure pertains from the following description.

### BRIEF DESCRIPTION OF THE DRAWINGS

FIG. 1 illustrates a semiconductor device comprising a deep trench capacitor according to an example of the present disclosure.

FIG. 2 illustrates a semiconductor device comprising a deep trench capacitor according to another example of the present disclosure.

FIGS. 3 to 12 illustrate a series of processes of a method for manufacturing a semiconductor device comprising a deep trench capacitor according to an example of the present disclosure.

Other features and aspects will be apparent from the following detailed description, the drawings, and the claims.

### DETAILED DESCRIPTION

The merits and characteristics of the present disclosure and a system, a device, and a method for achieving the merits and characteristics will become more apparent from the examples described in detail in conjunction with the accompanying drawings. However, the present disclosure is not limited to the disclosed examples, but may be implemented in various different ways. The examples are provided to only complete the disclosure of the present disclosure and to allow those skilled in the art to understand the category of the present disclosure. The present disclosure is defined by the category of the claims. The same reference numerals will be used to refer to the same or similar elements throughout the drawings.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. As used herein, the term “and/or” includes, but is not limited to any and all combinations of one or more of the associated listed items.

The terms used in the present specification are for describing examples and are not intended to limit the inventive concept. In the present specification, a singular form also includes a plural form unless particularly stated in the phrase. Components, steps, operations and/or elements that are referred to by terms “comprises” and/or “comprising” used in the inventive concept do not exclude presence or addition of one or more other components, steps, operations and/or elements.

Although the terms “first”, “second”, and the like are used for describing various components, these components are not confined by these terms. These terms are merely used for distinguishing one component from the other components.

Therefore, a first component to be mentioned below may be a second component in a technical concept of the present disclosure. Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the related art and will not be interpreted in an idealized or overly formal sense unless expressly so defined herein.

A term “part” or “module” used in the examples may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may include components such as software components, object-oriented software components, class components, and task components, and may include processes, functions, attributes, procedures, subroutines, segments of a program code, drivers, firmware, microcode, circuits, data, databases, data structures, tables, arrays, and variables. Components and functions provided in the “part” or “module” may be combined with a smaller number of components and “parts” or “modules” or may be further divided into additional components and “parts”or “modules”.

Methods or algorithm steps described relative to some examples of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the storage medium may reside in an application specific integrated circuit (ASIC). The ASIC may be resident within a user's terminal.

Hereinafter, a detailed description will be given as to the examples of the present disclosure with reference to the accompanying drawings in order for those skilled in the art to embody the present disclosure with ease. But the present disclosure is susceptible to variations and modifications and not limited to the examples described herein.

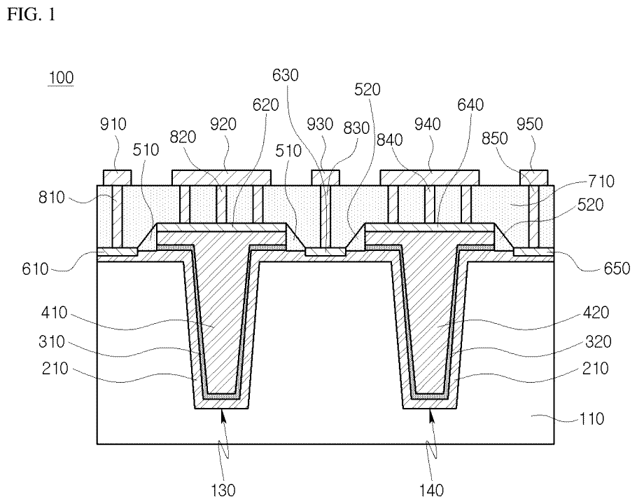

FIG. 1 illustrates a semiconductor device comprising a deep trench capacitor according to an example of the present disclosure.

Referring to FIG. 1, a semiconductor device 100 comprising a deep trench capacitor according to an example of the present disclosure may include a first deep trench 130 and a second deep trench 140 formed on a substrate 110; a highly doped first polysilicon layer 210 continuously formed in the first deep trench and the second deep trench; a first dielectric layer 310 and a second dielectric layer 320 formed in the first deep trench and the second deep trench, respectively, on the highly doped first polysilicon layer 210; a first upper electrode 410 and a second upper electrode 420 formed on the first dielectric layer and the second dielectric layer, respectively, and formed in the first deep trench and the second deep trench, respectively; a first spacer 510 formed on sidewalls of the first dielectric layer and the first upper electrode; a second spacer 520 formed on sidewalls of the second dielectric layer and the second upper electrode; a first silicide layer 610 formed on the highly doped first polysilicon layer adjacent to the first spacer; a second silicide layer 620 formed on the first upper electrode; a third silicide layer 630 formed on the highly doped first polysilicon layer between the first spacer and the second spacer; a fourth silicide layer 640 formed on the second upper electrode; a fifth silicide layer 650 formed on the highly doped first polysilicon layer adjacent to the second spacer; an inter-metal insulating layer 710 formed on the first to the fifth silicide layers; first to fifth contact plugs 810 to 850 formed inside the inter-metal insulating layer and connected to the first to the fifth silicide layers, respectively; and first to fifth metal layers 910 to 950 connected to the first to fifth contact plugs.

According to an example, the highly doped first polysilicon layer 210 may be continuously deposited in the first deep trench 130 and the second deep trench 140 without break. The highly doped first polysilicon layer 210 may be formed as a single continuous layer. Thus, the highly doped first polysilicon layer 210 may be referred to as a single continuous highly doped first polysilicon layer. The highly doped first polysilicon layer 210 may be used as a lower electrode or bottom electrode of a deep trench structure. The highly doped first polysilicon layer 210 has a dopant concentration ranged from 1E18 to 1E21 atoms/cm³. The highly doped first polysilicon layer 210 may be doped with dopants having a first conductivity type or a second conductivity type.

According to the example, the first dielectric layer 310 and the second dielectric layer 320 may be formed on the highly doped first polysilicon layer 210. The first dielectric layer 310 may be formed between the highly doped first polysilicon layer 210 and the first upper electrode 410. The second dielectric layer 320 may be formed between the highly doped first polysilicon layer 210 and the second upper electrode 420. The first dielectric layer 310 and the second dielectric layer 320 may comprise silicon oxide (SiO2), silicon oxynitride (SiON), silicon nitride (SiN), aluminum oxide (Al2O3), hafnium oxide (HF02), and other high-k material, or a combination thereof (e.g., Oxide/Nitride/Oxide, Nitride Oxide), but are not limited thereto.

According to the example, the first upper electrode 410 and the second upper electrode 420 may be formed on the first dielectric layer 310 and the second dielectric layer 320, respectively. The first upper electrode 410 and the second upper electrode 420 may be respectively formed in the first deep trench 130 and the second deep trench 140. The first upper electrode 410 and the second upper electrode 420 may comprise a highly doped polysilicon layer. The highly doped polysilicon layer may have a doping concentration ranged between 1E18 and 1E21 atoms/cm³. The highly doped polysilicon layer may be doped with dopants having a first conductivity type or a second conductivity type. Thus, the first upper electrode 410 and the second upper electrode 420 may have a doping concentration ranged between 1E18 and 1E21 atoms/cm³. The first upper electrode 410 and the second upper electrode 420 may be doped with dopants having a first conductivity type or a second conductivity type.

According to the example, the first spacer 510 and the second spacer 520 may comprise a silicon oxide layer, a silicon nitride layer, or a silicon oxynitride (SiON) layer. The first to the fifth silicide layers 610 to 650 may comprise materials such as titanium silicide (TiSi2), cobalt silicide (CoSi2), nickel silicide (NiSi) and the like, but are not limited thereto. Meanwhile, except an area for forming the contact plug on the upper electrode, the silicide layer may not be formed on the rest of areas of the upper electrode (not illustrated). This is to reduce unwanted leakage currents.

According to the example, the inter-metal insulation layer 710 may comprise a silicon oxide (SiO2) layer, tetraethyl orthosilicate (TEOS), a borophosphosilicate glass (BPSG), and the like, but is not limited thereto. The first to the fifth contact plugs 810 to 850 may comprise metals such as tungsten (W), copper (Cu), and the like, but are not limited thereto. The first to the fifth metal layers 910 to 950 may comprise materials such as aluminum (Al), copper (Cu), or the like, but are not limited thereto.

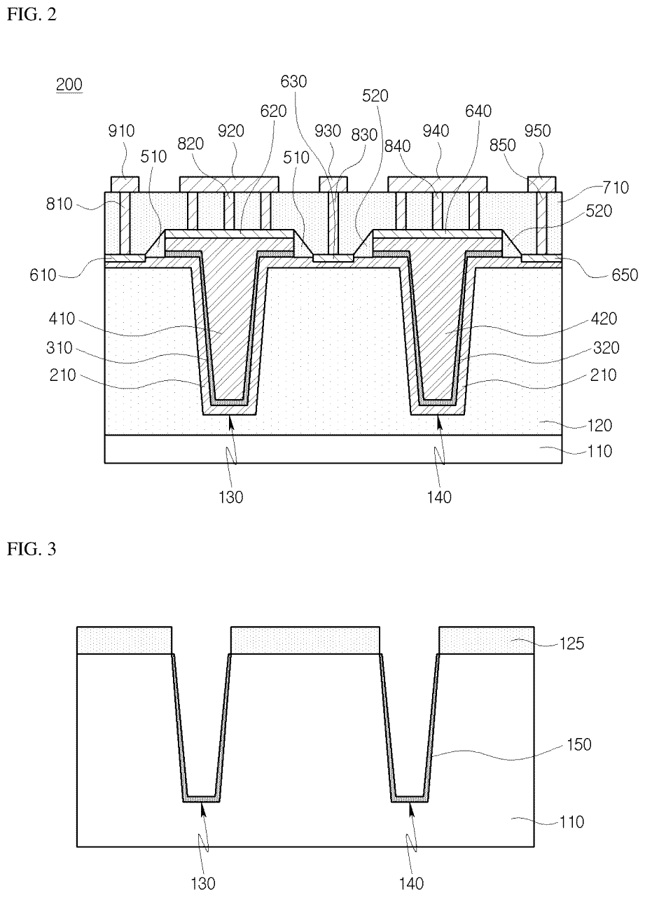

FIG. 2 illustrates a semiconductor device comprising a deep trench capacitor according to another example of the present disclosure. The structure is similar to that of FIG. 1, but has a difference in configuration of the substrate.

Referring to FIG. 2, a semiconductor device 200 comprising a deep trench capacitor according to another example of the present disclosure includes an epitaxial layer 120 formed on the substrate 110; the first deep trench 130 and the second deep trench 140 formed in the epitaxial layer 120; the highly doped first polysilicon layer 210 continuously formed in the first deep trench and the second deep trench; the first dielectric layer 310 and the second dielectric layer 320 formed in the first deep trench and the second deep trench, respectively, on the highly doped first polysilicon layer 210; the first upper electrode 410 and the second upper electrode 420 formed on the first dielectric layer 310 and the second dielectric layer 320, respectively, and formed in the first deep trench 130 and the second deep trench 140, respectively; the first space 510 formed on sidewalls of the first dielectric layer 310 and the first upper electrode 410; the second spacer 520 formed on sidewalls of the second dielectric layer 320 and the second upper electrode 420; the first silicide layer 610 formed on the highly doped first polysilicon layer 210 adjacent to the first spacer 510; the second silicide layer 620 formed on the first upper electrode 410; the third silicide layer 630 formed on the highly doped first polysilicon layer between the first spacer 510 and the second spacer 520; the fourth silicide layer 640 formed on the second upper electrode 420; the fifth silicide layer 650 formed on the highly doped first polysilicon layer 210 adjacent to the second spacer 520; the inter-metal insulating layer 710 formed on the first to the fifth silicide layers 610 to 650; the first to fifth contact plugs 810 to 850 formed inside the inter-metal insulating layer 710 and connected to the first to the fifth silicide layers 610 to 650, respectively; and the first to fifth metal layers 910 to 950 connected to the first to fifth contact plugs 810 to 850.

According to the example, the substrate 110 may have a first doping concentration in a range between 1E18 and 1E21 atoms/cm³, which is a high doping concentration. A parasitic leakage current may increase towards the substrate 110 due to unwanted operation of the parasitic PNP or the parasitic NPN that may occur between adjacent elements, but it is possible to reduce the parasitic leakage current by using the semiconductor substrate 110 having a high doping concentration. In addition, when the semiconductor substrate 110 having a high doping concentration is used, the device operation speed may be increased in Rf device, etc.

According to the example, the second doping concentration of the epitaxial layer 120 may be lower than the first doping concentration of the semiconductor substrate 110. The lower the doping concentration of the epitaxial layer 120, the higher the breakdown voltage of the semiconductor device 200 can be. Further, the epitaxial layer 120 may have the same conductivity type as that of the semiconductor substrate 110 or the opposite conductivity type to the semiconductor substrate 110. The present example took an example of including the semiconductor substrate 110 having the first conductivity type, and the epitaxial layer 120 having the first conductivity type. The rest of description of the example is similar to that described referring to FIG. 1, therefore, will be omitted.

Here, to simplify the manufacturing process and reduce manufacturing costs, the highly doped first polysilicon layer 210 may have the same conductivity type as the upper electrodes 410 and 420. The highly doped first polysilicon layer 210 may have the same doping concentration as the upper electrodes 410 and 420. Herein the highly doped first polysilicon layer 210 may be used as a lower electrode 210. The lower electrode 210 and the upper electrodes 410 and 420 may be made of the same material using the same equipment. If the lower electrode 210 is made of a different material than the upper electrodes 410 and 420, two different deposition equipment or two different chambers in one equipment are required to form the lower electrode 210 and the upper electrodes 410 and 420 separately. However, the lower electrode 210 may be made of the same material as the upper electrodes 410 and 420 in the present example, and two different deposition tools for the lower electrode 210 and the upper electrodes 410 and 420 are not required. Therefore, the manufacturing cost of the semiconductor device 100 or 200 comprising a deep trench capacitor may be reduced.

FIGS. 3 to 12 illustrate a series of processes for manufacturing a semiconductor device comprising a deep trench capacitor according to one example of the present disclosure.

FIG. 3 illustrates a process for manufacturing a semiconductor device comprising a deep trench capacitor inside a substrate.

Referring to FIG. 3, the first deep trench 130 and the second deep trench 140 may be formed on the substrate 110 by performing a deep trench etch process using a hard mask 125 and a lithography pattern (not illustrated). Here, the hard mask 125 may comprise a silicon oxide (SiO2), silicon nitride (SiN), tetraethyl orthosilicate (TEOS), or the like, but is not limited thereto.

A sacrificial oxide layer 150 may be formed over the first deep trench 130 and the second deep trench 140 by a thermal oxidation process after forming the first deep trench 130 and the second deep trench 140. The sacrificial oxide layer 150 may cure surface damages of the first deep trench 130 and the second deep trench 140 caused by the deep trench etching process performed on the substrate 110. Further annealing process may be performed on the sacrificial oxide layer 150. The hard mask 125 and the sacrificial oxide layer 150 may be removed after the annealing process.

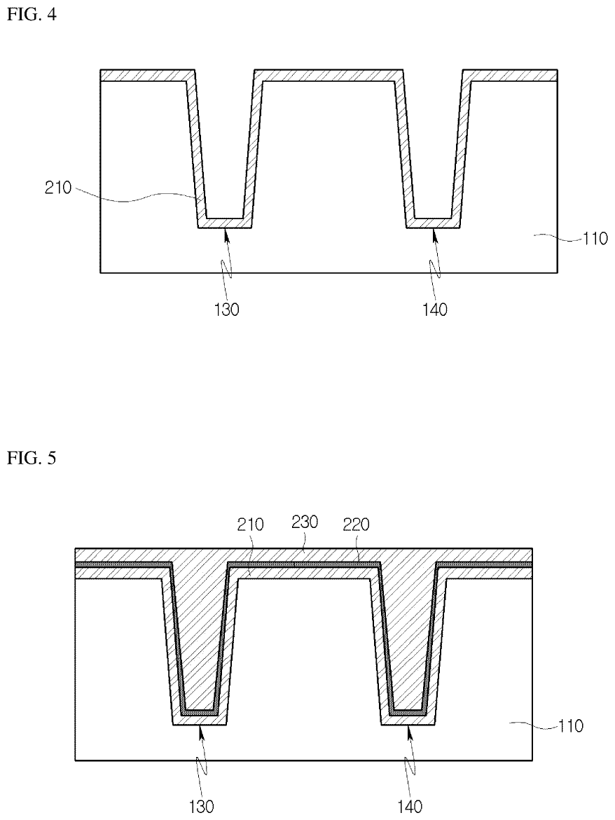

FIG. 4 illustrates a process for forming a highly doped first polysilicon layer to form a deep trench capacitor.

Referring to FIG. 4, the highly doped first polysilicon layer 210 may be deposited on sidewalls of the first deep trench 130 and the second deep trench 140. The highly doped first polysilicon layer 210 may be deposited with a N-type or P-type conductivity. The highly doped first polysilicon layer 210 may be generally formed by a low-pressure chemical vapor deposition (LPCVD) process. The conductivity type of the highly doped first polysilicon layer 210 depends on gases used in the LPCVD process. The highly doped first polysilicon layer 210 may have an N-type conductivity when POCl3 gas is in-situ added into a LPCVD chamber. To have a P-type conductivity, the highly doped first polysilicon layer 210 may be formed with boron-containing gases. The N-type or P-type polysilicon layer 210 may have a doping concentration ranged from 1E18 to 1E21 atoms/cm³, depending on a concentration of POCl3 or boron-containing gas.

The substrate 110 may suffer from a warpage or a bowing phenomenon because of a film stress caused by the highly doped first polysilicon layer 210 after the deposition of the highly doped first polysilicon layer 210. Therefore, a high temperature annealing process may be performed so as to release the film stress caused by the highly doped first polysilicon layer 210. The high temperature annealing process may be performed at a temperature of 900° C. to 1200° C. for 5 minutes to 4 hours by using a furnace or a rapid thermal annealing processing (RTP).

The high temperature annealing process may be performed using various gases such as argon (Ar) or nitrogen (N2), and oxygen (O2). The Ar or N2 belongs to an inert gas. Various gases can be used alone or in combination. For example, the high temperature annealing process may be performed in a gas mixture of the N2 and the O2. Herein, a partial pressure of the oxygen gas is less than 1% of a total pressure of the gas mixture. For another example, the high temperature annealing process may be performed in a gas mixture of Ar and O2, wherein a partial pressure of the O2 is less than 1% of a total pressure of the gas mixture. When applying the low partial pressure of O2, it may be helpful to reduce the film stress caused by the highly doped first polysilicon layer 210.

FIG. 5 illustrates a process for forming a dielectric layer and a highly doped second polysilicon layer to form a deep trench capacitor.

Referring to FIG. 5, the dielectric layer 220 may be formed on the highly doped first polysilicon layer 210. The dielectric layer 220 may be continuously formed in the first deep trench 130 and the second deep trench 140. The dielectric layer 220 may comprise silicon oxide (SiO2), silicon oxynitride (SiON), silicon nitride (SiN), aluminum oxide (Al2O3), hafnium oxide (HF02), and a high-k material, but is not limited thereto.

Next, a highly doped second polysilicon layer 230 may be deposited on the dielectric layer 220 to fill the first deep trench 130 and the second deep trench 140. The highly doped second polysilicon layer 230 may be formed using phosphorus-doped polycrystalline silicon or boron-doped polycrystalline silicon. A dopant concentration of the highly doped second polysilicon layer 230 may be ranged between 1E18 and 1E21 atoms/cm³. In addition, an etch-back process or a chemical mechanical planarization (CMP) process may be performed to planarize the highly doped second polysilicon layer 230.

After the highly doped second polysilicon layer 230 is deposited, a high temperature annealing process may be performed to release a film stress caused by the highly doped second polysilicon layer 230. The high temperature annealing process on the highly doped second polysilicon layer 230 is the same as the high temperature annealing process on the highly doped first polysilicon layer 210. Therefore, a detailed description thereof will be omitted.

Here, to simplify the manufacturing process and reduce a manufacturing cost, the highly doped first polysilicon layer 210 may have the same conductivity type as the highly doped second polysilicon layer 230. The highly doped first polysilicon layer 210 may have the same doping concentration as the highly doped second polysilicon layer 230. The highly doped first polysilicon layer 210 and the highly doped second polysilicon layer 230 are used as the lower electrode 210 and the upper electrodes 410 and 420, respectively. The highly doped first polysilicon layer 210 and the highly doped second polysilicon layer 230 may be composed of the same material using the same equipment. If the lower electrode 210 can be made of a different material than the upper electrodes 410 and 420, two different deposition equipment or two different chambers in one equipment are required to form the lower and upper electrodes 210, 410 and 420 separately. However, the lower electrode 210 may comprise the same material as the upper electrodes 410 and 420 in the present example, and two different deposition tools for the lower electrode 210 and the upper electrodes 410 and 420 are not required. Therefore, a manufacturing cost for the semiconductor device 100 or 200 comprising a deep trench capacitor may be reduced.

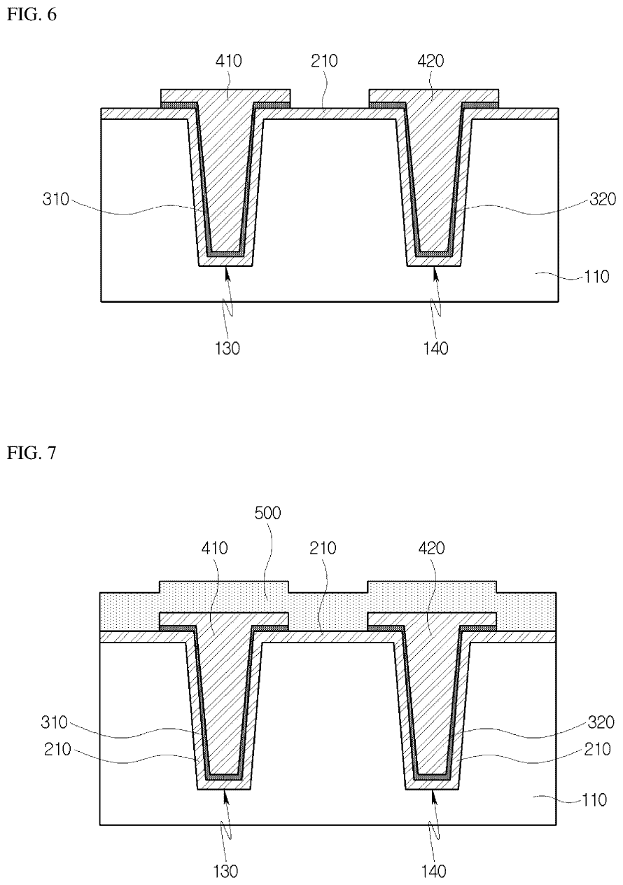

FIG. 6 illustrates a process for forming a deep trench capacitor.

Referring to FIG. 6, the first upper electrode 410 and the second upper electrode 420 may be formed by performing a patterning process on the highly doped second polysilicon layer 230. In the patterning process, the dielectric layer 220 may serve as an etch stop layer. During the patterning process, the dielectric layer 220 may be divided into the first dielectric layer 310 and the second dielectric layer 320. During the patterning process, the highly doped first polysilicon layer 210 may be exposed and slightly etched. The first dielectric layer 310 and the second dielectric layer 320 may be formed respectively in the first deep trench 130 and the second deep trench 140 after the patterning process of the dielectric layer 220.

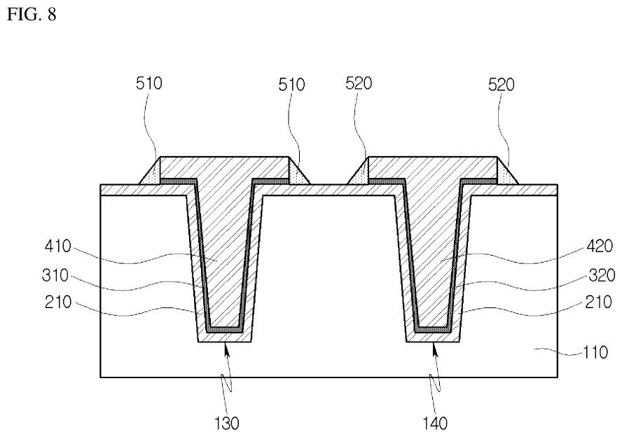

FIGS. 7 and 8 illustrate a process for forming a spacer to form the deep trench capacitor.

Referring to FIG. 7, an insulating layer 500 may be deposited on the highly doped first polysilicon layer 210, the first upper electrode 410 and the second upper electrode 420. The insulating layer 500 may fill the gap between the first upper electrode 410 and the second upper electrode 420. The insulating layer 500 may comprise a silicon oxide layer, a nitride layer, or an oxynitride layer. An etch-back process may be subsequently performed to form a spacer.

Referring FIG. 8, the first spacer 510 and the second spacer 520 may be formed by performing the etch-back process. The first spacer 510 may be formed on sidewalls of the first dielectric layer 310 and the first upper electrode 410. The second spacer 520 may be formed on sidewalls of the second dielectric layer 320 and the second upper electrode 420. The first spacer 510 and the second spacer 520 may directly be in contact with the highly doped first polysilicon layer 210.

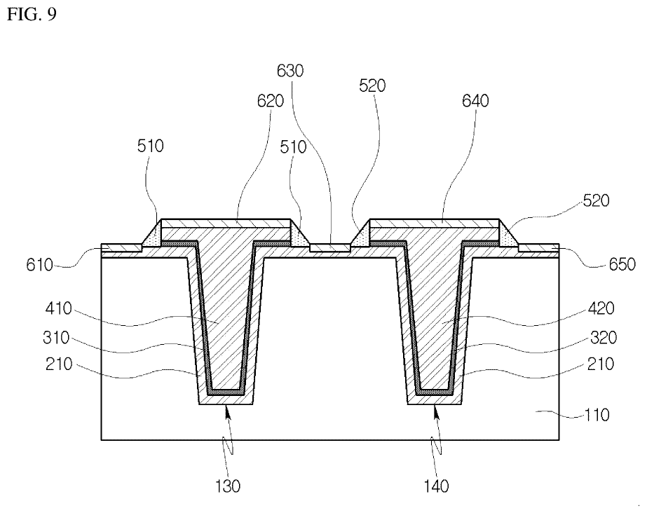

FIG. 9 illustrates silicide layers for forming the deep trench capacitor.

Referring to FIG. 9, the first to the fifth silicide layers 610 to 650 may be formed on upper surfaces of the first upper electrode 410 and the second upper electrode 420, and the highly doped first polysilicon layer 210. The first to fifth silicide layers 610 to 650 may include, but are not limited to, materials such as titanium silicide (TiSi2), cobalt silicide (CoSi2), and nickel silicide (NiSi).

The first silicide layer 610 may be formed on a left side of the highly doped first polysilicon layer 210 adjacent to the first spacer. The second silicide layer 620 may be formed on the first upper electrode 410. The third silicide layer 630 may be formed on a middle or center of the highly doped first polysilicon layer 210 disposed between the first spacer 510 and the second spacer 520. The fourth silicide layer 640 may be formed on the second upper electrode 420. The fifth silicide layer 650 may be formed on a right side of the highly doped first polysilicon layer 210 adjacent to the second spacer 520. Herein, the second silicide layer 620 and the fourth silicide layer 640 may have a horizontal length greater than a horizontal length of the first, third, and fifth silicide layers 610, 630 and 650, thereby covering a large area of the first and second upper electrodes 410 and 420.

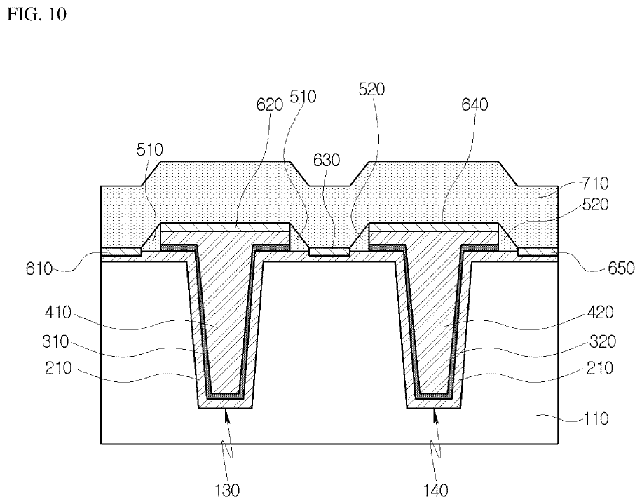

FIGS. 10 to 12 illustrate a process for forming an inter-metal insulating layer, contact plugs, and a metal layer for forming the deep trench capacitor.

Referring to FIG. 10, the inter-metal insulating layer 710 may be deposited on the highly doped first polysilicon layer 210, the first upper electrode 410 and the second upper electrode 420, and the first to the fifth silicide layers 610 to 650. The inter-metal insulating layer 710 may use a silicon oxide (SiO2) layer, tetraethyl orthosilicate (TEOS), a borophosphosilicate glass (BPSG), and the like. After depositing the inter-metal insulating layer 710, a planarization process may be performed on the inter-metal insulating layer 710.

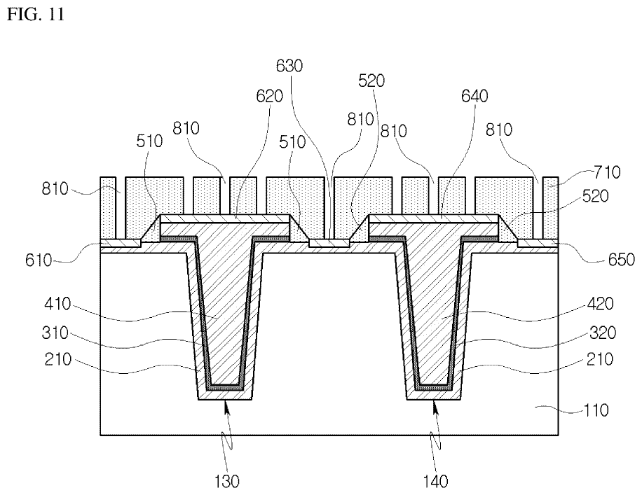

Referring to FIG. 11, by patterning the inter-metal insulating layer 710, a plurality of contact holes 810 may be formed. The first to the fifth silicide layers 610 to 650 may be exposed by the plurality of contact holes 810.

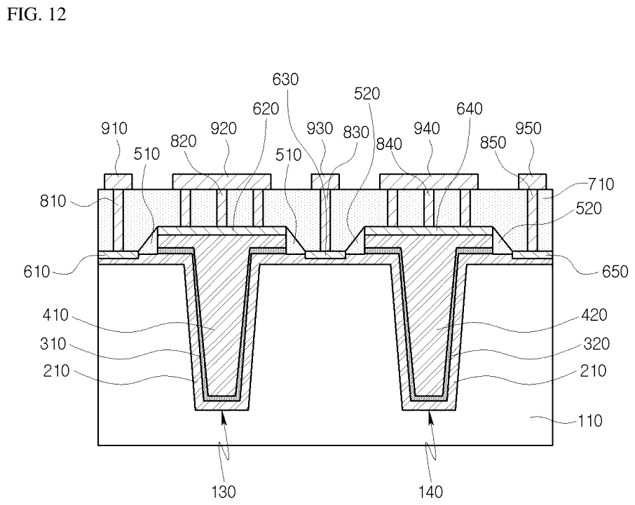

Referring to FIG. 12, a metal layer such as tungsten (W) or copper (Cu) may be deposited in the first to the fifth contact holes 810 to 850. After filling the metal layer into the contact holes, hereinafter, the contact holes may be referred to as contact plugs. The first to the fifth contact plugs 810 to 850 may be electrically connected to the first to the fifth silicide layers 610 to 650, respectively. The second contact plug 820 and the fourth contact plug 840 contact the second silicide layer 620 and the fourth silicide layer 640, respectively. The second contact plug 820 and the fourth contact plug 840 have at least two or three contact holes. The second and fourth contact plugs 820 and 840 are more numerous than the first, third and fifth contact plugs 810, 830 and 850 to cover a wide surface area of the silicide layer 620 and 640. Each of the first, third and fifth contact plugs 810, 830 and 850 has fewer contact holes than the second contact plug 820 or the fourth contact plug 840.

The first to the fifth metal layers 910 to 950 connected to the first to fifth contact plugs, respectively, may be formed. The first to the fifth metal layers 910 to 950 may comprise materials such as aluminum (Al), copper (Cu), or the like, but are not limited thereto.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Therefore, the scope of the disclosure is defined not by the detailed description, but by the claims and their equivalents, and all variations within the scope of the claims and their equivalents are to be construed as being included in the disclosure.

What is claimed is:

1. A method of manufacturing a semiconductor device comprising a deep trench capacitor, the method comprising:
forming a first deep trench and a second deep trench in a substrate;
forming a highly doped first polysilicon layer in the first deep trench and the second deep trench;
forming a dielectric layer on the highly doped first polysilicon layer;
forming a highly doped second polysilicon layer on the dielectric layer;
performing a first etch process on the highly doped second polysilicon layer to form a first upper electrode and a second upper electrode in the first deep trench and the second deep trench, respectively, wherein a first dielectric layer is formed between the first upper electrode and the highly doped first polysilicon layer and a second dielectric layer is formed between the second upper electrode and the highly doped first polysilicon layer by performing the first etch process;
forming an insulating layer on the first upper electrode and the second upper electrode;
performing a second etch process on the insulating layer to form a first spacer on sidewalls of the first dielectric layer and the first upper electrode and a second spacer on sidewalls of the second dielectric layer and the second upper electrode;
forming a silicide layer on the highly doped first polysilicon layer, the first upper electrode and the second upper electrode;
forming an inter-metal insulating layer on the silicide layer;
forming contact plugs on the silicide layer; and
forming a metal layer connected to each of the contact plugs,
wherein the highly doped first polysilicon layer is a single continuous layer in the first deep trench and the second deep trench.

2. The method of claim 1, wherein the silicide layer comprises:
a first silicide layer disposed on the highly doped first polysilicon layer adjacent to the first spacer;
a second silicide layer disposed on the first upper electrode and having a horizontal length greater than a horizontal length of the first silicide layer;
a third silicide layer disposed on the highly doped first polysilicon layer located between the first spacer and the second spacer;
a fourth silicide layer disposed on the second upper electrode and having a horizontal length greater than a horizontal length of the first silicide layer; and
a fifth silicide layer disposed on the highly doped first polysilicon layer adjacent to the second spacer.

3. The method of claim 1, wherein a doping concentration of the highly doped first polysilicon layer is the same as a doping concentration of the first upper electrode and the second upper electrode, and
wherein the doping concentration of the highly doped first polysilicon layer is in a range of 1E18 to 1E21 atoms/cm³.

4. The method of claim 2, wherein a number of the contact plugs formed on the second or fourth silicide layer is greater than a number of the contact plugs formed on the first, third, or fifth silicide layer.

5. The method of claim 1, further comprising:
performing a high temperature annealing process on the highly doped first polysilicon layer or the highly doped second polysilicon layer in a gas mixture of oxygen gas and inert gas,
wherein a partial pressure of the oxygen gas is less than 1% of a total pressure of the gas mixture.

6. The method of claim 1, wherein the substrate comprises a highly doped substrate and an epitaxial layer, and
wherein the first and second deep trenches are formed in the epitaxial layer.

7. A semiconductor device comprising a deep trench capacitor, the device comprising:
a first deep trench and a second deep trench formed in a substrate;
a single continuous highly doped first polysilicon layer disposed in the first deep trench and the second deep trench;
a first dielectric layer and a second dielectric layer formed on the single continuous highly doped first polysilicon layer and disposed in the first deep trench and the second deep trench, respectively;
a first upper electrode and a second upper electrode formed on the first dielectric layer and the second dielectric layer, respectively, and formed in the first deep trench and the second deep trench, respectively;
a first spacer formed on sidewalls of the first dielectric layer and the first upper electrode;
a second spacer formed on sidewalls of the second dielectric layer and the second upper electrode;
a first silicide layer formed on the single continuous highly doped first polysilicon layer adjacent to the first spacer;
a second silicide layer formed on the first upper electrode, the second silicide layer having a horizontal length greater than a horizontal length of the first silicide layer;
a third silicide layer formed on the single continuous highly doped first polysilicon layer disposed between the first spacer and the second spacer;
a fourth silicide layer formed on the second upper electrode, the fourth silicide layer having a horizontal length greater than a horizontal length of the first silicide layer;
a fifth silicide layer formed on the single continuous highly doped first polysilicon layer adjacent to the second spacer;
an inter-metal insulating layer formed on the first to the fifth silicide layers;
a first contact plug, a second contact plug, a third contact plug, a fourth contact plug and a fifth contact plug connected to the first, second, third, fourth and fifth silicide layers, respectively; and
a first metal layer, a second metal layer, a third metal layer, a fourth metal layer and a fifth metal layer connected to the first, second, third, fourth and fifth contact plugs, respectively.

8. The device of claim 7, wherein a doping concentration of the single continuous highly doped first polysilicon is in a range of 1E18 to 1E21 atoms/cm³.

9. The device of claim 7, wherein the substrate comprises a highly doped substrate and an epitaxial layer, and
wherein the first and second deep trenches are formed in the epitaxial layer.

10. The device of claim 7, wherein the single continuous highly doped first polysilicon layer comprise a same material as the first and second upper electrodes.

11. The device of claim 7, wherein each of the second contact plug and the fourth contact plug has at least two contact holes, and each of the first, third and fifth contact plugs has fewer contact holes than the second or fourth contact plug.
